(19) United States
(12) Patent Application Publication
(10) Pub. No.: US 2007/0103206 A1
(43) Pub. Date: May 10, 2007

(54) Constant voltage diode

(76) Inventors: Susumu Murakami, Hitachinaka (JP); Akihiro Nakahara, Kai (JP); Minoru Nakamura, Hitachinaka (JP); Masahiro Nakaya, Kai (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/594,121

(22) Filed: Nov. 8, 2006

(30) Foreign Application Priority Data
Nov. 8, 2005 (JP) JP2005-323385

(51) Int. Cl. H03B 1/00

(52) U.S. Cl. 327/108

(57) ABSTRACT

A plurality of recesses are provided on a first main surface of an n-type semiconductor region of a semiconductor chip forming a constant voltage diode, and a p⁺⁺-type semiconductor region is provided on the first main surface including inner faces of the plurality of recesses. Thereby, a portion of a depletion layer width with high voltage dependency and a portion thereof with low voltage dependency can be provided at a p-n junction portion of the constant voltage diode formed by the p⁺⁺-type semiconductor region and the n-type semiconductor region. As a result, a leakage current can be reduced in a blocking state where a breakdown voltage of the p-n junction portion of the constant voltage diode is set to be low. Accordingly, a leakage current of a constant voltage diode can be lowered.

### CROSS-REFERENCE TO RELATED APPLICATION

The present application claims priority from Japanese Patent Application No. JP 2005-323385 filed on Nov. 8, 2005, the content of which is hereby incorporated by reference into this application.

### TECHNICAL FIELD OF THE INVENTION

The present invention relates to a technology for a constant voltage diode, and in particular to improvement of rectifying characteristic in a p-n junction.

### BACKGROUND OF THE INVENTION

As a constant voltage diode used so as to prevent application of a voltage equal to or more than a fixed voltage utilizing a breakdown voltage of the diode, a zener diode or a surge absorber diode has been known. For example, in a semiconductor device and a method for manufacturing the same described in Japanese Patent Application Laid-Open Publication No. 2004-06676, fluctuation with time of a reverse breakdown voltage in can be prevented by, regarding an impurity concentration in at least one of a p-type impurity diffusion layer and an n-type impurity diffusion layer constituting a p-n junction in a semiconductor device, making the impurity concentration at a portion contacting with a device isolation film lower than that in the other portion in order to improve stability of reverse breakdown voltage.

In a constant voltage diode described in Japanese Patent Application Laid-Open Publication No. H10-163507, for example, regarding a zener diode including a first conductivity type semiconductor layer for Zener characteristic that is formed on a first conductivity type semiconductor substrate and has a resistivity defined depending on the Zener characteristic and a second conductivity type semiconductor region that is provided on the semiconductor layer for Zener characteristic, secondary breakdown can be effectively caused to improve breakdown strength to surge without increasing series resistance by providing a semiconductor layer with resistivity higher than that of the semiconductor substrate between the semiconductor layer for Zener characteristic and the semiconductor substrate.

In a method for manufacturing a semiconductor device described in Japanese Patent Application Laid-Open Publication No. H06-29557, for example, by adopting a p-n junction formed by applying diffusion of impurity to a recess formed on a surface of a first conductivity type semiconductor layer to form a second conductivity type region or a hybrid structure of the p-n junction and a Schottky barrier, effective joint area can be increased so that voltage loss in a forward direction can be reduced.

In a semiconductor device described in Japanese Patent Application Laid-Open Publication No. H09-82986, for example, tradeoff between ON voltage and switching loss is improved simultaneously with reduction in leakage current by using a high concentration n-type semiconductor substrate as an n⁺ buffer layer, forming an n⁻ layer on the n⁺ buffer layer, forming p⁻ layer on a surface layer of the n⁻ layer, forming a trench groove reaching the n⁻ layer on a surface of the p⁻ layer, vapor-depositing boron on sidewalls and a bottom face of the trench groove to form a p⁺ region, forming a front face electrode on the p⁻ layer and p⁺ region, and forming a back face electrode on the n⁺ buffer layer.

In a semiconductor device described in Japanese Patent Application Laid-Open Publication No. 2001-44400, for example, by forming a joint area of a p-n junction in an uneven shape, a p-n junction area can be increased without increasing a volume of a heat sensitive portion, so that a semiconductor infrared ray detecting element with high sensitivity and excellent response can be realized.

### SUMMARY OF THE INVENTION

However, the present inventors found that the constant voltage diodes described above include the following problem.

That is, in a constant voltage diode utilizing a breakdown voltage of a p-n junction to be used to prevent application of a voltage equal to or more than a constant voltage, when a value of a constant voltage is lowered, such a problem arises that a leakage current increases at a voltage blocking state.

In view of these circumstances, an object of the present invention is to provide a technology that can reduce a leakage current in a constant voltage diode.

The above and other objects and novel characteristics of the present invention will be apparent from the description of this specification and the accompanying drawings.

The typical ones of the inventions disclosed in this application will be briefly described as follows.

That is, the present invention is constituted to utilize a breakdown mechanism in a constant voltage diode as avalanche to provide a curvature to a p-n junction that causes breakdown.

The effects obtained by typical aspects of the present invention will be briefly described below.

That is, a leakage current from a constant voltage diode can be reduced by utilizing the breakdown mechanism in the constant voltage diode as avalanche to provide a curvature to a p-n junction which causes breakdown.

However, the present inventors found that the constant voltage diodes described above include the following problem.

That is, in a constant voltage diode utilizing a breakdown voltage of a p-n junction to be used to prevent application of a voltage equal to or more than a constant voltage, when a value of a constant voltage is lowered, such a problem arises that a leakage current increases at a voltage blocking state.

In view of these circumstances, an object of the present invention is to provide a technology that can reduce a leakage current in a constant voltage diode.

The above and other objects and novel characteristics of the present invention will be apparent from the description of this specification and the accompanying drawings.

The typical ones of the inventions disclosed in this application will be briefly described as follows.

That is, the present invention is constituted to utilize a breakdown mechanism in a constant voltage diode as avalanche to provide a curvature to a p-n junction that causes breakdown.

The effects obtained by typical aspects of the present invention will be briefly described below.

That is, a leakage current of a constant voltage diode can be reduced by utilizing the breakdown mechanism in the constant voltage diode as avalanche to provide a curvature to a p-n junction which causes breakdown.

### BRIEF DESCRIPTIONS OF THE DRAWINGS

FIG. 1 is, on the upper side thereof a plan view of a semiconductor chip having a constant voltage diode according to an embodiment of the present invention seen from the above, and on the lower side thereof a sectional view of the semiconductor chip having a constant voltage diode shown on the upper side, taken along a line A-A;

FIG. 2A is a sectional view after main steps for manufacturing the constant voltage diode shown in FIG. 1;

FIG. 2B is a sectional view after main steps for manufacturing the constant voltage diode shown in FIG. 1;

FIG. 2C is a sectional view after main steps for manufacturing the constant voltage diode shown in FIG. 1;

FIG. 2D is a sectional view after main steps for manufacturing the constant voltage diode shown in FIG. 1;

FIG. 2E is a sectional view after main steps for manufacturing the constant voltage diode shown in FIG. 1;

FIG. 2F is a sectional view after main steps for manufacturing the constant voltage diode shown in FIG. 1;

FIG. 2G is a sectional view after main steps for manufacturing the constant voltage diode shown in FIG. 1;

FIG. 3 is an enlarged perspective view of a plurality of recesses formed on a first main surface of the constant voltage diode shown in FIG. 1;

FIG. 4A-1 is an explanatory diagram showing a shape of a depletion layer obtained when a reverse bias voltage is applied to the constant voltage diode;

FIG. 4A-2 is an explanatory diagram showing a shape of a depletion layer obtained when a reverse bias voltage is applied to the constant voltage diode;

FIG. 4A-3 is an explanatory diagram showing a shape of a depletion layer obtained when a reverse bias voltage is applied to the constant voltage diode;

FIG. 4B-1 is an explanatory diagram showing an energy band structure at breakdown;

FIG. 4B-2 is an explanatory diagram showing an energy band structure at breakdown;

FIG. 4B-3 is an explanatory diagram showing an energy band structure at breakdown;

FIG. 5 is a partially exploded perspective view showing an overview of the constant voltage diode shown in FIG. 1 that is sealed by mold resin;

FIG. 6 is a graph showing characteristic of the constant voltage diode shown in FIG. 1;

FIG. 7 is, on the upper side thereof a plan view of a semiconductor chip having a constant voltage diode according to another embodiment of the present invention seen from the above, and on the lower side thereof a sectional view of the semiconductor chip having a constant voltage diode shown on the upper side, taken along a line B-B;

FIG. 8 is an enlarged perspective view of a plurality of recesses formed on a first main surface of the constant voltage diode shown in FIG. 7;

FIG. 9 is a partially exploded plan view of a diode module including the constant voltage diode with a package constitution explained in FIG. 5 and other passive parts in the same or one package; and

FIG. 10 is a sectional view of a main portion of the diode module shown in FIG. 9.

### DESCRIPTIONS OF THE PREFERRED EMBODIMENTS

In embodiments described below, although the explanation is made in a plurality of divided sections or embodiments for convenience sake if necessary, the sections or embodiments have any relationship among them except for specific indications and one thereof relates to a variation, details, supplemental explanation, or the like of some or all of the others. In the following embodiments, when the number of elements or the like (including the number of pieces, a numerical value, an amount, a range, and the like) is shown in explanation thereof, the number is not limited to a specific number shown therein, and the number may be more than or less than the specific number except for a case that there is a specific indication, a case that it is apparent that the number is principally limited to a specific one, or the like. Similarly, in the following embodiments, when a shape of a constituent element or the like, a positional relationship, or the like is described, it can include shapes substantially approximate to or similar to the shape or the like except for a case that there is a specific indication, a case that it is thought that a shape should be apparently denied principally, or the like. This can be similarly applied to the numerical value and the range. In all figures for explaining the embodiments, parts or portions having same function are denoted by the same reference numerals and repetitive explanation thereof are omitted as far as possible. Hereinafter, the embodiments of the present invention will be explained in detail with reference to the drawings.

### First Embodiment

In a first embodiment is, for lowering a breakdown voltage of the constant voltage diode, increasing an impurity concentration forming a p-n junction to prevent increase of a leakage current due to utilization of Zener breakdown where tunneling current flows. Thereby achieving a constant voltage diode with a low leakage current even with a low breakdown voltage. Such an object is achieved by lowering a breakdown voltage owing to local electric field at the p-n junction having unevenness (curvature).

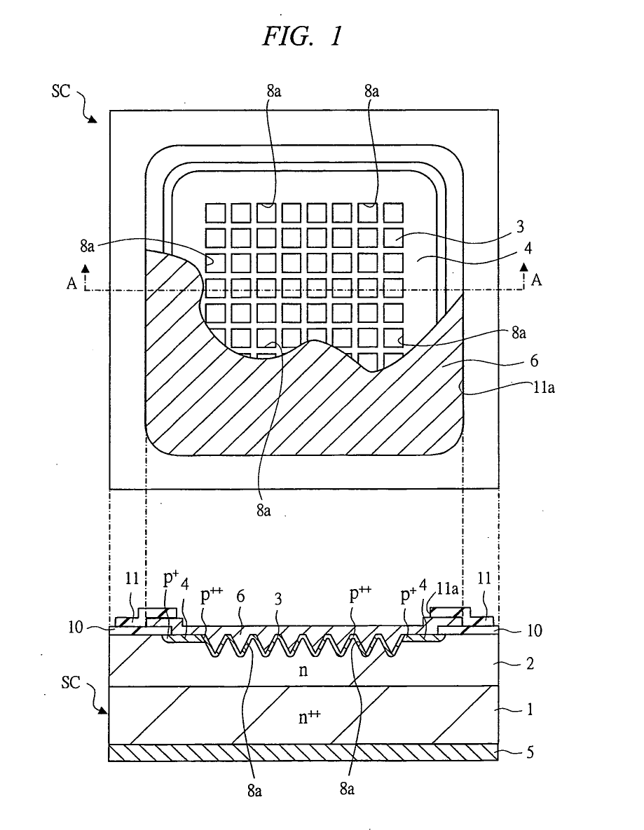

The upper side of FIG. 1 is a plan view of a semiconductor chip having the constant voltage diode according to an embodiment of the present invention, as seen from the above, and the lower side thereof is a sectional view of the semiconductor chip having the constant voltage diode shown on the upper side of FIG. 1, taken along a line A-A in FIG. 1. A portion on the plan view at the upper side of FIG. 1 is attached with hatching for ease of viewing and a portion of semiconductor chip is exploded for making a lower layer thereof visible.

A semiconductor chip SC is composed of, for example, a single crystal silicon (Si), and it has a first main surface and a second main surface positioned on opposite sides to each other along a thickness direction thereof. A size of the semiconductor chip SC in plan view is not limited to a specific one, but it may be about 200 μm×200 μm, for example. A breakdown voltage of the constant voltage diode formed on the semiconductor chip SC is not limited to a specific value, but it may be 5V or less, for example.

In FIG. 1, the reference numeral 1 denotes an n⁺⁺-type semiconductor region (a first semiconductor region) with high impurity concentration (a first impurity concentration), 2 denotes an n-type semiconductor region (a second semiconductor region) with a second impurity concentration lower than that of the n⁺⁺-type semiconductor region 1, which is formed on the n⁺⁺-type semiconductor region 1 so as to contact with the same by epitaxial method, 3 denotes a p⁺⁺-type semiconductor region (a third semiconductor region) with a third impurity concentration higher than the second impurity concentration, which is formed on a main surface (the first main surface of the semiconductor chip SC) of the n-type semiconductor region 2 that is processed to be uneven, and 4 denotes a p⁺-type semiconductor region (a fourth semiconductor region) with a fourth impurity concentration lower than the third impurity concentration and higher than the second impurity concentration, which is formed on an outer peripheral portion (an outer periphery of the uneven region) of the p⁺⁺-type semiconductor region 3.

A cathode electrode (a second electrode) 5 is formed on a back face (the second main surface of the semiconductor chip SC) of the n⁺⁺-type semiconductor region 1 in an ohmic contact state with the semiconductor region 1. An anode electrode (a first electrode) 6 is formed on a main surface (the first main surface of the semiconductor chip SC) of the n-type semiconductor region 2 in an ohmic contact state with the p⁺⁺-type semiconductor region 3 and the p⁺-type semiconductor region 4. The constant voltage diode is used in such a state that the p-n junction formed by the p⁺⁺-type semiconductor region 3 and the n-type semiconductor region 2 is reverse-biased by applying negative voltage to the anode electrode 6 and positive voltage to the cathode electrode 5.

A plurality of recesses 8a extending in a direction crossing the first main surface of the n-type semiconductor region 2 are regularly arranged on the first main surface at desired intervals. For example, each recess 8a is formed in a rectangular cone shape (conical shape). That is, the recess 8a is formed in a square shape in plan view, it is formed in a V shape in sectional view, and it is formed in a shape projecting from the first main surface of the semiconductor chip SC in a thickness direction of the semiconductor chip SC. The p⁺⁺-type semiconductor region 3 is formed in a direction crossing the first main surface including respective inner faces of the plurality of recesses 8a. Besides, the p⁺-type semiconductor region 4 is formed adjacent to the p⁺⁺-type semiconductor region 3 at an outer periphery of a formation region of the plurality of recesses 8a in a direction crossing the first main surface.

In FIG. 1, the reference numeral 10 denotes a first passivation film formed of a thermal oxidation SiO₂ film, phosphosilicate glass, or the like, and 11 denotes a second passivation film made from silicon nitride (P—SiN) or the like formed on the first passivation film 10 and the anode electrode 6 by plasma CVD or the like. An opening 11a is formed at a portion of the second passivation film 11, and a portion of a surface of the anode electrode 6 is exposed from the opening 11a.

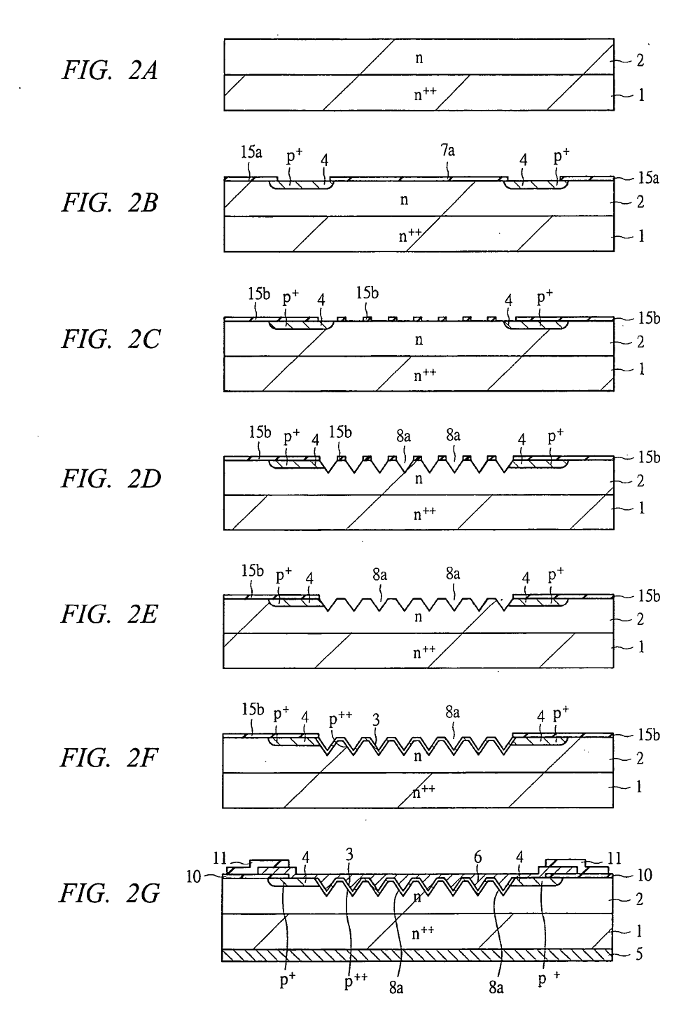

Next, FIGS. 2A to 2G are sectional views after main steps for manufacturing the constant voltage diode shown in FIG. 1. One example of a method for manufacturing the constant voltage diode according to the first embodiment will be explained below with reference to FIGS. 2A to 2G.

A: The n-type semiconductor region 2 is formed on the n⁺⁺ type semiconductor region 1 by epitaxial method. Phosphorus (P), antimony (Sb), or arsenic (As) is contained as impurity in the n-type semiconductor region 2 at high concentration of 1×10¹⁶ to 1×10¹⁸ cm⁻³;

B: An oxide film 15a is formed on the n-type semiconductor region 2, a portion of the oxide film 15a is removed by ordinary lithography, and the p⁺-type semiconductor region 4 containing boron (B) as impurity at a concentration of 1×10¹⁸ to 1×10¹⁹ cm⁻³ is selectively formed;

C: Next, the oxide film 15a formed at the step B is once removed, an oxide film 15b is newly formed, and the oxide film 15b is then bored by ordinary photo-etching;

D: Thereafter, the plurality of recesses 8a are formed by anisotropic alkaline etching using, for example, KOH, NaOH, or the like in order to form the p⁺⁺-type semiconductor region 3 with a high impurity concentration according to the first embodiment;

E: Next, the oxide films 15b remaining at the recesses 8a are removed by ordinary photo-etching;

F: Thereafter, the p⁺⁺-type semiconductor region 3 including impurity, for example, at a concentration of 1×10¹⁹ to 1×10²⁰ cm⁻³ is formed in a region of the first main surface of the semiconductor region 2 where the plurality of recesses 8a are formed by introducing, for example, boron from the first main surface side of the n-type semiconductor region 2 by thermal diffusion or ion-implantation; and

G: The oxide film 15b formed at the above step is once removed, an oxide film is newly formed by thermal oxidization or CVD, the first passivation film 10 made of phosphosilicate glass (PSG) film is further formed, the first passivation film 10 is then bored by photo-etching process, aluminum (Al) or silicon (Si)-containing aluminum is evaporated on the first main surface of the semiconductor region 2, and the anode electrode 6 is formed by applying ordinary photo-etching process on the aluminum. Thereafter, the second passivation film 11 made of plasma-nitrided silicon film or the like is formed on the first main surface, and a portion of the anode electrode 6 is exposed by performing patterning by ordinary photo-etching. Finally, after the cathode electrode 5 is formed on a back surface by evaporating a gold or gold-antimony electrode, thermal processing is performed at a temperature of 300 to 450° C. after the evaporation.

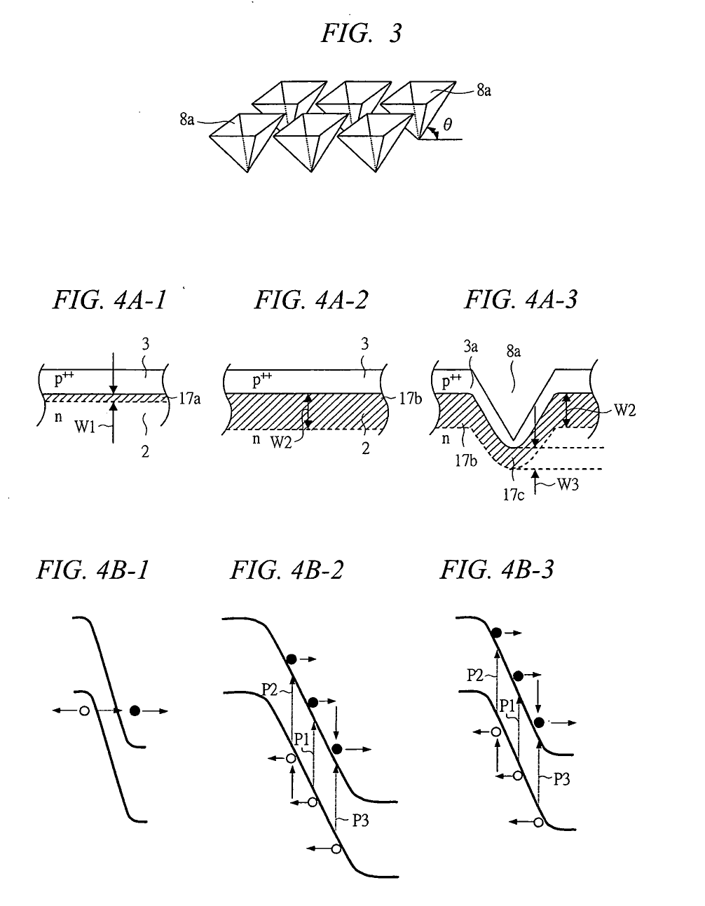

FIG. 3 is an enlarged perspective view of the plurality of recesses 8a of the constant voltage diode according to the first embodiment. The shape of the recesses Ba can be formed by utilizing the orientation of the first main surface of the silicon substrate (the n-type semiconductor region 2) as (100) face, shaping the shape of the opening portions of the oxide film 15b formed on the first main surface of the n-type semiconductor region 2 as an etching mask to a predetermined shape (here, square), and etching the n-type semiconductor regions 2 exposed from the opening portions using alkaline solution containing KOH or NaOH. For example, when alkaline etching is performed using alkaline solution whose NaOH or KOH concentration is in a range of 5 wt % to 65 wt % and whose temperature is in a range of 25° C. to 115° C., the recess 8a having a square cone shape whose side face is (111) face can be obtained. The cubic shape of such a recess 8a can be excellently formed by utilizing a difference in etching rate between the (100) face and the (111) face. The recess 8a is formed, for example, in a rectangular cone shape where an angle defined by two faces (side faces) of each recess 8a facing each other is, for example, 70.6 degrees. Reduction of the angle defined by two faces of the recess 8a opposed to each other becomes more effective for lowering the breakdown voltage of the constant voltage diode. In the recess 8a in FIG. 3, the angle θ of the side face of the recess 8a to the main surface of the n-type semiconductor region 2 is 54.7 degrees, for example.

When the p ⁺⁺-type semiconductor region 3 with a high impurity concentration is formed in the recess 8a shown in FIG. 2, the bottom of the recess 8a is formed in a projecting shape. A feature of the constant voltage diode according to the first embodiment lies in that a breakdown voltage is determined by utilizing local high electric field at the projection. An operation of the determination will be explained below with reference to the drawings.

FIGS. 4A-1 to 4B-3 are diagrams for explaining an operation of the constant voltage diode according to the first embodiment, FIGS. 4A-1 to 4A-3 are diagrams showing states of a depletion layer obtained when a reverse bias voltage has been applied to the constant voltage diode, and FIGS. 4B-1 to 4B-3 are energy band diagrams at respective breakdown.

FIGS. 4A-1 and 4B-1 are diagrams showing a case of an ordinary zener diode, where, in a case where a reverse bias voltage is applied such that the p⁺⁺-type semiconductor region 3 becomes negative and the n-type semiconductor region 2 becomes positive, when an impurity concentration in semiconductors forming the p-n junction is made high so that electric field intensity becomes high, as shown in FIG. 4B-1, electrons leaving from the valence band move through the depletion layer 17a shown in FIG. 4A-1 to the conduction band due to tunneling effect. Therefore, breakdown occurs at a voltage lower than a voltage where avalanche breakdown occurs when a width W1 of the depletion layer 17a is set to be considerably thin. A breakdown voltage utilizing the tunneling effect can lower a breakdown voltage as compared with a case where ordinary avalanche breakdown phenomenon is utilized, however, since a leakage current at a voltage blocking state flows due to tunneling effect even with slight application of a voltage, large current that can not be considered as leakage current flows when a reverse voltage is applied.

On the other hand, an ordinary avalanche diode is the same as the zener diode in such a point where a reverse bias voltage is applied such that the P⁺⁺-type semiconductor region 3 becomes negative and the n-type semiconductor region 2 becomes positive, as shown in FIGS. 4A-2 and 4B-2, but a width W2 of the depletion layer 17b shown in FIG. 4A-2 can be made thicker than the width W1 of the depletion layer 17a shown in FIG. 4A-1 by lowering the impurity concentration of at least one of the semiconductors forming the p-n junction. At this time, as shown in FIG. 4B-2, when the electric field intensity becomes high, electrons leaving from the valence band can not pass through the depletion layer 17b shown in FIG. 4B-1 utilizing tunneling effect, as shown by an arrow P1, so that, when the electrons move in electric field, electron-hole pairs are further generated, as shown by arrow P2 or arrow P3. Thus, since the width W2 of the depletion layer 17b is large in the avalanche breakdown, the electron-hole pairs generated under intense electric field causes breakdown at a voltage higher than the Zener breakdown voltage. However, since generation current due to carriers generated in the depletion layer is generally dominant in a leakage-current flow mechanism, such a merit can be obtained that the leakage current can be made lower than that in the zener diode.

As explained above, in the ordinary zener diode, the breakdown voltage can be lowered but the leakage current increases. That is, when a p-n junction diode formed by making two semiconductor regions different in conductivity type having high impurity concentrations to contact with each other is a zener diode, there is such a problem that very large leakage current flows in a voltage range lower than a Zener breakdown voltage in a blocking state due to application of reverse bias. On the other hand, in the avalanche diode, the leakage current can be reduced but such a problem arises that the breakdown voltage can not be lowered.

In the constant voltage diode according to the first embodiment, as shown in FIG. 4A-3, by forming the p⁺⁺-type semiconductor region 3a to have V-shaped side faces, the width W2 of the depletion layer 17b except for the V shape in plan view can be set to the same as the width shown in FIG. 4A-2, but a width W3 of the depletion layer 17c at an acute angle portion positioned at the V-shaped bottom can be made narrower than the width W2. Since the width W3 is made larger than the width W1 such that the tunneling current does not flow in a thermal equilibrium state where voltage is not applied, the impurity concentration in the n-type semiconductor region 2 is made lower than the case shown in FIG. 4A-1. Thereby, since tunneling current does not flow, leakage current becomes generation current generated in the depletion layer so that it can be made less than the tunneling current. That is, since the p-n junction constituting the constant voltage diode according to the first embodiment has unevenness and the mechanism based upon avalanche breakdown where electric field becomes high at the projecting portion of the semiconductor on the high impurity concentration side is utilized, the leakage current is not tunneling current appearing in the zener diode but it is a generation current in the depletion layer expanding on both sides of the p-n junction, so that such a merit is obtained that the leakage current can be reduced considerably.

On the other hand, the breakdown voltage depends on avalanche breakdown in the case shown in FIG. 4B-3 like the operation explained in FIG. 4B-2, but the depletion layer 17c has a curvature, so that such a merit can be obtained that the breakdown voltage can be set to be lower than the breakdown voltage determined depending on a plane junction of the width W2 of the depletion layer 17b. That is, in the first embodiment, the width of the depletion layer expanding on both sides of the p-n junction is made large in a voltage blocking state such that tunneling current does not flow and a potion of the depletion layer width with high voltage dependency and a portion thereof with low voltage dependency are provided in a blocking state where reverse bias is applied so that a low breakdown voltage even equal to that in the ordinary zener diode can be realized and the breakdown voltage of the p-n junction can be set to be low while the avalanche breakdown is utilized.

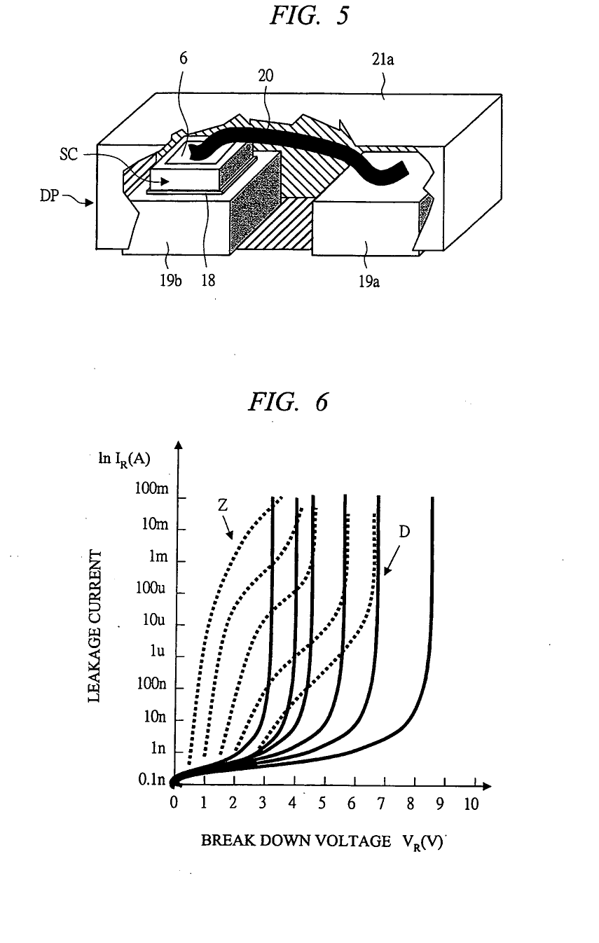

Next, FIG. 5 is a partially exploded perspective view showing an overview of the constant voltage diode according to the first embodiment that is sealed by mold resin. In FIG. 5, a second lead electrode 19b is connected to the cathode electrode 5 (see FIG. 1) on the back face (the second main surface) of the constant voltage diode via solder 18 and a wire 20 connects the anode electrode 6 on the main surface (the first main surface) of the constant voltage diode and a first lead electrode 19a using wire bonding. Further, a surface mount type constant voltage diode DP is completed by sealing the whole constant voltage diode (portions of the first lead electrode 19a and the second lead electrode 19b and the whole of the semiconductor chip SC and the wire 20) except for portions of the first lead electrode 19a and the second lead electrode 19b using mold resin 21a. The portions of the first lead electrode 19a and the second lead electrode 19b are exposed from the same face of the mold resin 21a.

According to the first embodiment, since the constant voltage diode can be incorporated into a small-sized package whose volume is equal to or less than 1 mm³, for example, size reduction and weight reduction of parts can be achieved.

Next, FIG. 6 is a graph showing characteristics of the constant voltage diode according to the first embodiment. In the graph, reference character Z (a broken line) denotes breakdown characteristic of a zener diode manufactured by an ordinary process, while reference character D (a solid line) denotes breakdown characteristic obtained when the avalanche breakdown mechanism explained in the first embodiment is utilized. As shown in FIG. 6, when the breakdown voltage in the zener diode manufactured by the ordinary process is set to about 4V, the leakage current reaches such a high value as 100 μA, but such a considerably low value as 10 nA can be obtained according to the first embodiment.

Thus, the constant voltage diode according to the present embodiment is a constant voltage diode utilizing a low breakdown voltage due to avalanche breakdown voltage and a leakage current in a voltage blocking state can be lowered, so that power consumption can be suppressed to be low and power loss can be reduced largely by using the constant voltage diode of the embodiment for application of a common zener diode.

### Second Embodiment

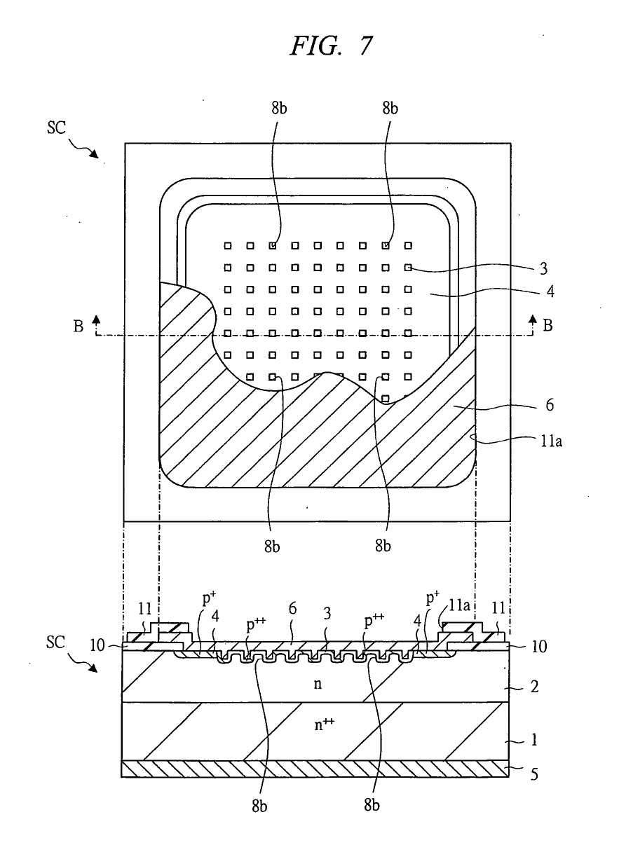

The upper side of FIG. 7 is a plan view of a semiconductor chip having a constant voltage diode according to another embodiment of the present invention, as seen from the above, and the lower side thereof is a sectional view of the semiconductor chip having the constant voltage diode shown at the upper side of FIG. 7, taken along a line B-B in FIG. 7. A portion on the plan view at the upper side of FIG. 7 is attached with hatching for ease of viewing and a portion of semiconductor chip is exploded for making a lower layer thereof visible.

In the second embodiment, recesses 8b formed on a first main surface of an n-type semiconductor region 2 are formed in, for example, a rectangular columnar shape (columnar shape, or hexahedron). That is, the recess 8b is formed in a square shape coinciding with a bottom of the hexahedron in plan view, and it is formed in a box shape (a rectangular shape) in section. A size of the recess 8a in plan view is smaller than that of the recess 8b in the first embodiment. Thereby, as explained regarding the recess 8a, an effect similar to such effect where reduction in angle defined by faces facing each other becomes more effective for lowering breakdown voltage of a constant voltage diode is obtained, so that the breakdown voltage of the constant voltage diode can be lowered.

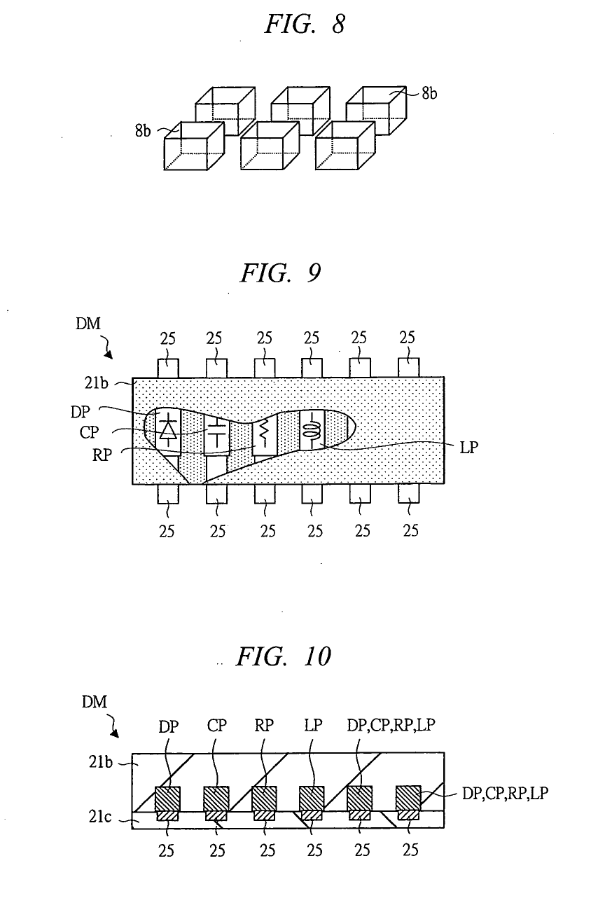

FIG. 8 is an enlarged perspective view of the plurality of recesses 8b of the constant voltage diode according to the second embodiment. The shape of the recesses 8a can be obtained by utilizing the orientation of the silicon substrate (the first main surface of the n-type semiconductor region 2) as (−100) face, shaping the shape of the opening portions of the oxide film 15b (see FIG. 2C) formed on the first main surface of the n-type semiconductor region 2 as an etching mask to a predetermined shape (here, a square shape), and etching the n-type semiconductor regions 2 exposed from the opening portions using alkaline solution containing KOH or NaOH. For example, when alkaline etching is performed using alkaline solution whose NaOH or KOH concentration is in a range of 5 wt % to 65 wt % and whose temperature is in a range of 25° C. to 115° C., the recess 8b having a hexahedron whose side face is the (111) face can be obtained. The cubic shape of the recess 8b in this case can be excellently formed by utilizing a difference in etching rate between the (−110) face and the (111) face. The second embodiment is similar to the first embodiment except for the above-described matters.

In the case such as the second embodiment, a low breakdown voltage compared to that in an common zener diode can be realized according to operation and effect similar to those in the first embodiment, and a leakage current can be lowered remarkably.

### Third Embodiment

FIG. 9 shows an example where not only the constant voltage diode DP with the package configuration explained in FIG. 5 but also passive parts with package configuration such as a capacitor CP, a resistor RP, and an inductance LP are assembled as one diode module DM. FIG. 10 is a sectional view of a main portion of the diode module DM shown in FIG. 9.

The reference numeral 25 denotes a lead electrode required in use as a module, where, for example, the lead electrode 25 is electrically connected to the first lead electrode 19a and the second lead electrode 19b of the constant voltage diode DP shown in FIG. 5 via solder. Similarly, the capacitor CP, the resistor RP, and the inductance LP that are other passive parts are electrically connected to respective lead electrodes and the lead electrode 25 of the diode module DM via solder or the like. The constant voltage diode DP, the capacitor CP, the resistor RP, and the inductance LP, and a portion of the lead electrode 25 are covered with mold resins 21b and 21c. Thereby, the diode module DM is formed.

All of the passive parts proceed to module configurations according to spreading of recent mobile devices. As explained above, the constant voltage diode DP according to the present embodiment is suitable for size reduction, and it is also suitable for configuring a diode module DM incorporated with a resister RP, an inductance LP, a capacitor CP, and the like those are passive parts.

In the foregoing, the invention made by the inventors of the present invention has been concretely described based on the embodiments. However, it is needless to say that the present invention is not limited to the foregoing embodiments and various modifications and alterations can be made within the scope of the present invention.

For example, the shapes of the recesses 8a and 8b in plan view may be triangular shapes, when the first main surface of the n-type semiconductor region 2 is seen. In this case, the first main surface of the n-type semiconductor region 2 formed with the recess is defined to be (111) face. The shapes of the recesses 8a and 8b in plan view may be circular shapes.

Further, for example, the recess 8b may be formed by dry etching process.

The present invention can be applied to a manufacturing industry of a constant voltage diode.

What is claimed is:

1. A constant voltage diode including a semiconductor chip having a first main surface and a second main surface positioned on sides opposite to each other,
the semiconductor chip comprising:
a first semiconductor region of a first conductivity type with a first impurity concentration having the second main surface;
a second semiconductor region of the first conductivity type with a second impurity concentration lower than that of the first impurity concentration, which is formed on the first semiconductor region and has the first main surface;
a plurality of recesses provided on the first main surface of the second semiconductor region;
a third semiconductor region of a second conductivity type opposite to the first conductivity type with a third impurity concentration higher than the second impurity concentration, which is formed in a direction crossing the first main surface including respective inner faces of the plurality of recesses;
a fourth semiconductor region of the second conductivity type with a fourth impurity concentration lower than the third impurity concentration and higher than the second impurity concentration, which is formed in a direction crossing the first main surface at an outer periphery of a region where the plurality of recesses are formed and adjacent to the third semiconductor region;
a first electrode which is formed so as to make ohmic contact to the third and fourth semiconductor regions on the first main surface; and
a second electrode which is formed to make ohmic contact to the first semiconductor region on the second main surface, wherein
a p-n junction formed by the second semiconductor region and the third semiconductor region is used in a reverse-biased state.

2. The constant voltage diode according to claim 1, wherein the shape of each recess is a cone shape.

3. The constant voltage diode according to claim 2, wherein a orientation of a semiconductor crystal on the first main surface is (100) face.

4. The constant voltage diode according to claim 1, wherein a shape of each recess is a columnar shape.

5. The constant voltage diode according to claim 1, wherein a orientation of a semiconductor crystal on the first main surface is (−110) face.
